(19) United States
(12) Patent Application Publication
(10) Pub. No.: US 2024/0363489 A1
(43) Pub. Date: Oct. 31, 2024

(54) CHIP STACK AND FABRICATION METHOD

(71) Applicant: Yibu Semiconductor Co., Ltd., Shanghai (CN)

(72) Inventor: Ming Li, Fremont, CA (US)

(73) Assignee: Yibu Semiconductor Co., Ltd., Shanghai (CN)

(21) Appl. No.: 18/754,081

(22) Filed: Jun. 25, 2024

(30) Foreign Application Priority Data
Apr. 26, 2023 (CN) 202310465741.6

(51) Int. Cl. H01L 23/473; H01L 21/304; H01L 21/306; H01L 21/308; H01L 23/00; H01L 23/48; H01L 25/18; H10B 80/00

(52) U.S. Cl. CPC H01L 23/473; H01L 21/304; H01L 21/30604; H01L 21/308; H01L 23/481; H01L 24/80; H01L 24/08; H01L 24/16; H01L 25/18; H01L 2224/08146; H01L 2224/16145; H01L 2224/16225; H01L 2224/80895; H01L 2224/80896; H01L 2225/06513; H01L 2225/06517; H01L 2924/1431; H01L 2924/1436; H10B 80/00

(57) ABSTRACT

The present disclosure relates to a chip stack in the semiconductor field and a method of manufacturing the same. The chip stack comprises a plurality of stacked chips, the active surface of a first chip of the plurality of chips facing the passive surface of a second chip immediately below the first chip, and at least one open cavity embedded in the passive surface of the second chip forming a closed micro-channel with the active surface of the first chip. The microchannels in the stacked chips allow cooling micro-fluid to be introduced into the microchannels. The micro-fluid can flow from one chip to another, taking away heat generated by the chips, allowing heat dissipation of the chip stack to meet industry requirement. The micro-channels for dissipating the heat are formed while the chips are stacked. Thus, besides forming the micro-channels, no additional process steps are required to form the chip stack.

### CROSS REFERENCE TO RELATED APPLICATION

This application claims the benefit of priority under the Paris Convention to Chinese Patent Application No. 202310465741.6A, filed on Apr. 26, 2023, which is incorporated herein by reference in its entirety.

### TECHNICAL FIELD

The present disclosure relates to the field of semiconductor technology and particularly to a chip stack and a method of fabrication.

### BACKGROUND

With the development of integrated circuit technology, 3D and 2.5D system-in-package (SiP) and through-silicon via (TSV) technologies are becoming increasingly mature, providing a foundation for developing high bandwidth and large capacity memory products.

To meet the ever-growing demands on bandwidth, capacity and low power consumption for DRAM (Dynamic random-access memory) products, the JEDEC (Joint Electron Device Engineering Council) Solid State Technology Association has published the HBM (High Bandwidth Memory) standards for four generations, namely HBM1, HBM2, HBM2E, and the newest HBM3 (JESD238 High Bandwidth Memory), which was issued on Jan. 28 2022. HBM3's technical merits are greatly improved compared with HBM2 and HBM2E standards. An HBM3 chip features a total bandwidth reaching 819.2 GB/s with a single pin data rate reaching 6.4 Gbit/s, 16 memory layer (chip) stacking support, a maximum storage capacity of up to 64 GB, and sets the development direction for the next generation of high bandwidth memory.

As shown in FIGS. 1 & 2, the HBM interconnects vertically stacked DRAM chips using TSVs and micro bumps to form a three-dimensional chip stack that breaks through performance limitations for DRAM products, greatly improving memory capacity and providing a very high memory bandwidth. However, in JESD238 HMB3, the maximum stacking height is set to 745 μm, and if more DRAM chips are to be stacked, the heights of the chips and the sizes of the micro bumps need to be reduced. This reduction in height will cause the chip stacking density of the HBM3 to increase, generating more heat. If the original heat dissipation method is still applied, the heat cannot be dissipated effectively, resulting in failure to meet the HBM3 specification.

### SUMMARY

To address the above technical problems, the present disclosure provides a chip stack and a method for manufacturing the same.

In some embodiments, a chip stack comprises a plurality of stacked chips. The passive surface of each of at least some of the stacked chips comprises at least one embedded open cavity. In two adjacent first and second chips among the plurality of stacked chips, the active surface of the first chip faces the passive surface of the second chip. When these two surfaces are bonded together, the at least one open cavity on the second chip is closed to form a micro-channel.

In some embodiments, the open cavity has a target depth of 10 μm to 150 μm and a target width of 30 μm to 200 μm.

In some embodiments, the cross section of each open cavity along a thickness direction has a somewhat rectangular or trapezoidal or semicircular shape.

In some embodiments, each chip in the chip stack further comprises through holes penetrating the chip and conductive posts positioned in the through holes. The penetrating direction of the through holes is parallel to the stacking direction of the chips, and the position of each through holes are located away from any open cavity (so the through holes do not run through any part of any open cavity). In some embodiments, conductive posts in the through holes of one chip are bonded with the conductive posts in the through holes of an adjacent chip.

In some embodiments, the chip stack includes at least one of a high bandwidth memory chip and a System-on-Chip (SoC).

In some embodiments, a method for fabricating a chip stack comprises forming at least one embedded open cavity on the passive side of each of a plurality of chips, and stacking the chips to form a chip stack. For every two adjacent chips in the chip stack, the active surface of a first chip faces the passive surface of a second chip, and each open cavity on the second chip form a closed micro-channel with the active surface of the first chip.

In some embodiments, the at least one embedded open cavity on the passive surface of the chip is formed by photolithographic masking followed with wet or dry etching.

In some embodiments, forming at least one embedded open cavity on the passive surface of a chip further includes forming an open cavity with a first depth on the passive surface of the chip, wherein the first depth is greater than a target depth for the embedded open cavity, and then thinning the passive surface of the chip by a polishing and/or grinding process and controlling the final depth of the open cavity to be at the target depth.

In some embodiments, a wafer stack is formed by stacking a plurality of wafers, each wafer including a set of chips, each chip including through holes penetrating the chip in the stacking direction of the chips and at least one open cavity on the passive side of the chip. The positions of the through holes are located away from any open cavity, and conductive posts is formed in each through holes. The wafer stack is formed by bonding and connecting the conductive posts of the chips on one wafer with the corresponding conductive posts of the chips on an adjacent wafer. The wafer stack can be diced to obtain individual chip stacks.

In some embodiments, the bonding and connecting of the conductor post of a chip with the conductor post of an adjacent chip in the chip stack or wafer stack includes: connecting the conductive posts of the chip with the conductive posts of the adjacent chips using a hybrid bonding process.

Compared with the prior technologies, the technical scheme provided by the disclosure has the following advantages:

The micro-channels between the chips in a stack can be filled with cooling micro-fluid to take away heat generated by the chips so that the heat dissipation of the chip stack can meet the specification requirement; in addition, the micro-channels for heat dissipation are formed while stacking the chips, so no extra working procedure is needed, and the preparation process is simplified.

### BRIEF DESCRIPTION OF THE DRAWINGS

The accompanying drawings, which are incorporated in and constitute a part of this specification, illustrate embodiments consistent with the disclosure and, together with the description, explain the principles of the disclosure.

In order to more clearly illustrate the embodiments of the present disclosure, the drawings required for the description of the embodiments will be briefly described below, and it will be obvious to those skilled in the technologies that other drawings can be obtained from these drawings without effort.

FIG. 1 is a schematic diagram of a chip stack according to the related technologies.

FIG. 2 is a schematic diagram of another chip stack provided in the related technologies.

FIG. 3A is a schematic structural diagram of a chip stack according to an embodiment of the present disclosure.

FIGS. 3B-3C are plan views of active and passive sides, respectively, of a chip in the chip stack according to certain embodiments.

FIG. 3D is a plan view of the passive side of another chip in the chip stack in accordance with some embodiments.

FIGS. 4A-4B are a schematic cross-sectional diagram of a single chip according to an embodiment of the present disclosure.

FIGS. 5A-5B are plan views of active and passive sides, respectively, of a chip in the chip stack according to certain embodiments.

FIG. 5C is a schematic structural diagram of a chip stack according to an embodiment of the present disclosure.

FIGS. 6-8 are flow charts illustrating a method for fabricating a chip stack according to an embodiment of the present disclosure.

FIG. 9 is a schematic structural diagram of a wafer including a set of chips according to an embodiment of the present disclosure.

FIG. 10 is a flow chart of a method of temperature control for a chip stack according to some embodiments.

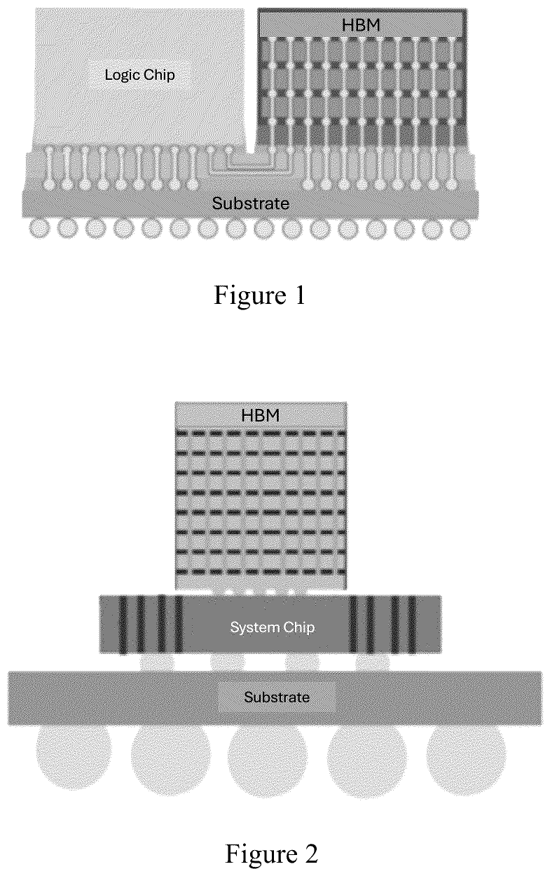

### DETAILED DESCRIPTION OF THE EMBODIMENTS

In order that the above objects, features and advantages of the present disclosure may be more clearly understood, a further description of aspects of the present disclosure will be provided below. It should be noted that, if there is no conflict, the embodiments of the present disclosure and features of the embodiments can be combined with each other.

In the following description, numerous specific details are set forth to provide a thorough understanding of the present disclosure, but the present disclosure can also be implemented in other ways different from those described here; it will be obvious that the embodiments in the specification are only some, but not all, embodiments of the disclosure.

Among related technologies, a substrate is arranged at the bottom and/or the top of a chip stack, a micro-fluid channel is arranged in the substrate, and the heat dissipation of the chip is realized by introducing flowing cooling fluid into the micro-fluid channel to take away heat generated by the chip; the micro-fluid channel is positioned at the bottom and/or the top of the chip stack. The cooling fluid can only rapidly take away the heat generated by the chips positioned at the top and the bottom of the chip stack, so the microfluidic channel is suitable when the number of layers in the chip stack is small. The heat generated by the chips positioned in the middle layer cannot be taken away when the number of layers in the chip stack is large, and the heat dissipation cannot meet the specification requirement.

To solve this technical problem, embodiments of the present disclosure provide a chip stack and a method for manufacturing the same, wherein the chip stack comprises adjacent chips where the active surface of one chip is facing the passive surface of the other chip, and the open cavity forms a closed micro-channel with the active surface. When the chips are stacked and bonded together, the open cavity on the passive surface of the chip is tightly attached to the active surface of the adjacent chip to form a closed micro-channel so that micro-channels exist between the chips of adjacent layers, and the micro-channels are filled with cooling micro-fluid to take away heat generated by the chips so that the heat dissipation is sufficient to meet the specification requirement. In addition, the micro-channels for heat dissipation are formed while the chips are being stacked. Thus, besides forming the micro-channels, no additional process steps are required to form the chip stack according to certain embodiments.

With the development of 3D system-in-package technology, the requirements for memory bandwidth and capacity are increasing. The number of stacked layers of the chip stack is increasing such that more than 16 layers are possible, and the problem of heat dissipation of the chip stack needs to be solved. The technical solutions provided by the embodiments of the present disclosure are suitable for stacking chips with different numbers of stacking layers while meeting the heat dissipation specification. The heat dissipation will not be weakened by an increase in the number of stacking layers; the more stacking layers there are, the better the heat dissipation will be. Compared with the existing technical solution and related technologies, the heat dissipation is prominent.

The following is an exemplary description of the chip stacking and preparation methods provided by the embodiments of the present disclosure with reference to the accompanying drawings.

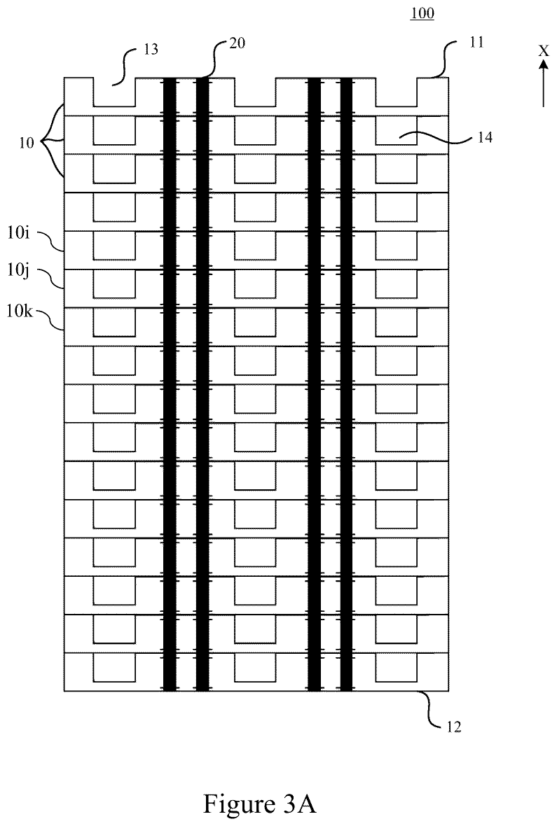

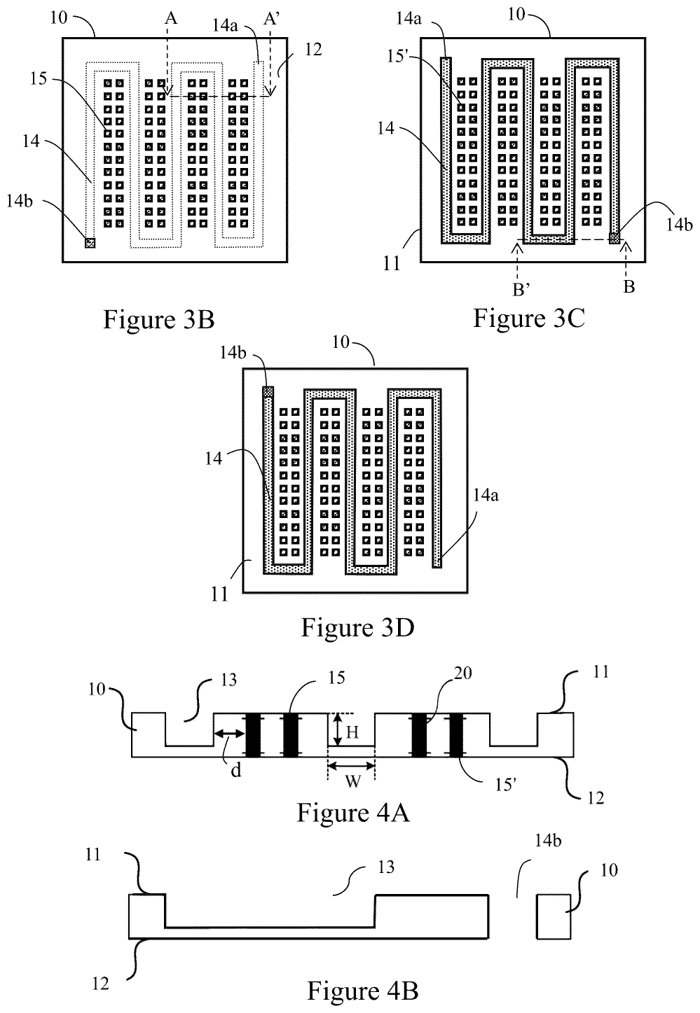

FIG. 3A is a schematic structural diagram of a chip stack 100 according to an embodiment of the present disclosure, and FIG. 4A is a schematic structural diagram of a single chip 10 according to an embodiment of the present disclosure. Referring to FIGS. 3A and 4A, the chip stack 100 includes a plurality of chips 10 that are stacked. Each passive surface 11 of at least some of the chips 10 in the chips stack 100 comprises at least one open cavity 13. For any two adjacent chips, the active surface 12 of a first chip 10 of the adjacent two chips faces the passive surface 11 of a second chip 10 of the two adjacent chips. Thus, the open cavities 13 on the second chip 10 of the two adjacent chips are embedded in the chip stack 100 and form closed micro channels 14 with the passive service 12 of the first chip 10.

Each chip 10 can be any of various types of chips known to those skilled in the technologies, such as at least one of Random Access Memory (RAM), Dynamic Random Access Memory (DRAM), Static RAM (SRAM), High Bandwidth Memory (HBM), Logic Chip, and System on Chip (SoC), without limitation.

Each chip 10 in the chip stack 100 includes a passive surface (or passive side) 11 and an active surface (or active side) 12, where the active side 12 is formed with active devices and an Input/Output (I/O) interface, and the passive side 11 is provided with at least one embedded open cavity, i.e., an open trench. The stacking of multiple chips 10 may be accomplished using Hybrid Bonding (HB) or other bonding means known to those skilled in the technologies, thereby forming a chip stack 100.

In the process of stacking the chips 10, the passive surface 11 of one chip 10 is connected with the active surface 12 of another chip 10 in a face-to-face manner. In some embodiments, the passive surface 11 of one chip is tightly attached to the active surface 12 of another chip. The open cavity 13 on the passive surface 11 thus forms a closed or embedded cavity with the active surface 12. The closed cavity can serve as a micro-channel 14 for cooling with microfluid. The surfaces of the open cavity 13 serve as the side surface and the bottom surface of the micro-channel 14. The active surface 12 serves as the top surface of the micro-channel 14.

FIG. 3B-3C are plan views of the active and passive sides, respectively, of a chip 10 (e.g., chip 10i shown in FIG. 3A) in the chip stack 100, showing a plurality of metal pads 15 on the active side 12, and a corresponding plurality of pads 15 and a microchannel 14 on the passive side 11 of the chip 10, according to certain embodiments. The micro-channel 14 is shown to have at least one inlet 14a and at least one outlet 14b, so cooling micro-fluid can be introduced into the micro-channel 14 from the inlet, and heat generated by the chip is absorbed by the cooling micro-fluid flowing through the microchannel and is carried out of the chip stack by the cooling micro-fluid through the outlet 14b, so that cooling and heat dissipation of the chip and the adjacent chip are realized. After cooling treatment, the cooling micro-fluid flowing out of the outlet of the micro-channel 14 on one chip flows to the inlet of another chip by a through via at the outlet of the one chip and/or the inlet of the other chip. After the microfluid flows through a stack of chips, it is cooled and recycled to the inlet of the micro-channel 14 of a top chip or a bottom chip of the stack of chips again. The present disclosure is not limited to using the cooling microfluid, and any fluid having a cooling function, such as water and/or ethylene glycol, known to those skilled in the technologies may be used.

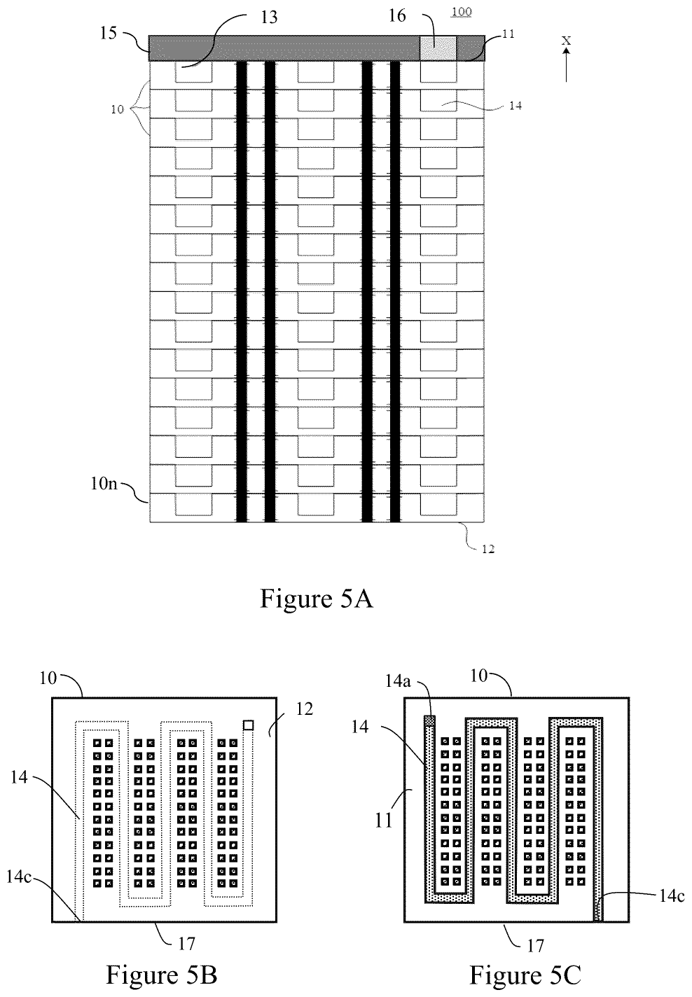

In some embodiments, as shown in FIG. 5A, the chip stack further includes a top layer chip 15 having one or more through vias 16 through which microfluid is injected into the microchannel on the chip 10 immediately below the top layer chip 15. The microfluid flows through the microchannel(s) 14 on the chip 10 before exiting the microchannel(s) 14 on this chip by the through via 14b thereon and entering the microchannel(s) on the chip 10 immediately below. The microfluid thus runs through the microchannels of a stack of chips before exiting the chip stack and is recycled back to the top layer chip 15 and injected into the stack of chips again.

In some embodiments, as shown in FIGS. 5B and 5C, the microchannel on an exit chip (e.g., chip 10n shown in FIG. 5A), from which the microfluid exit the stack of chips, has a slightly different configuration from the microchannel 14 on each of the other chips in the stack of chips. For example, the outlet 14c of the microchannel 14 on the exit chip 10 is at an edge 17 of the chip, instead of a via through the chip. This allows the microfluid to exit the chip stack and be collected and recycled.

With this arrangement, in the chip stack 100, the passive surface of each layer of chips is provided with micro-channels for cooling and heat dissipation. By passing the cooling microfluid through the micro-channels, the cooling microfluid is used to take away heat generated in the corresponding layer. The heat generated by the chip, even by chips in the layers located in the middle of the chip stack, can be effectively dissipated, allowing the chip stack to meet applicable specification requirements.

FIG. 4A shows a cross-section taken across line A-A′ of the chip 10 shown in FIGS. 3B-3C. FIG. 4B shows a cross-section taken across line B-B′ of the chip 10 shown in FIGS. 3B-3C. As shown, the outlet 14b of the chip 10 includes a through via to allow the microfluid to flow from the micro-channel 14 of the chip 10 to the inlet of the micro channel in an adjacent chip (e.g., chip 10j shown in FIG. 3A) immediately below the chip 10. FIG. 3D is a plan view of the passive side of the adjacent chip 10, showing that position of the inlet 14a of a microchannel 14 on the adjacent chip 10 corresponds to the position of the outlet 14b of the chip 10 shown in FIG. 3B. The position of the outlet 14b of the microchannel 14 on the chip 10 shown in FIG. 3D would correspond to inlet 14a of the microchannel 14 on another chip 10 (e.g., chip 10k shown in FIG. 3A) immediately below the chip shown in FIG. 3D. Thus, the microchannel 14 on chip 10k can have the same plan view as the microchannel on chip 10i, which is shown in FIGS. 3B-3C.

It can be understood that FIG. 3A only illustrates that the number of layers of the chip stack is 16 but the number of layers in the chip stack is not limited to any particular number in the embodiments of the present disclosure. For example, the number of stacked layers of the chip stack can be 2 layers or above, such as 4 layers, 8 layers, 12 layers, 16 layers, or more than 16 layers.

The chip stack 100 provided in the embodiment of the present disclosure includes a plurality of chips 10 that are stacked, the passive surface 11 of each chip 10 comprising at least one embedded open cavity 13, the active surface 12 of one chip 10 of any adjacent two chips 10 facing the passive surface 11 of the other chip 10, and the open cavities 13 at the passive surface form closed micro-channels 14 with the active surface 12. When the chips 10 are stacked together, the open cavity 13 positioned on the passive surface 11 of the chip 10 is tightly attached to the active surface 12 of the adjacent chip 10 to form the enclosed micro-channel 14 so that the micro-channels 14 exist between the chips 10 of the adjacent layers, and the micro-channel 14 can be filled with cooling micro-fluid so that the micro-fluid is utilized to take away heat generated by the chips, and the heat dissipation can meet the specification requirement. In addition, the micro-channels 14 for cooling and heat dissipation are formed while stacking the chips 10 and no additional process is required, simplifying the manufacturing process.

In some embodiments, as shown in FIG. 4, the open cavity 13 has a target depth H of 10 μm to 150 μm and a target width W of 30 μm to 200 μm.

The surface area of the micro-channel 14 is proportional to the target depth H and the target width W of the open cavity 13. The surface area of the micro-channel 14 is the contact area between the cooling micro-fluid and the chip 10, and the larger the contact area between the cooling micro-fluid and the chip 10 is, the better the heat dissipation is. Since the stacking operation of the chips 10 is also required, the chips are required to have a certain strength, and space needs to be reserved in the passive surface 11 for setting up the bonding sites. Also, the flow rate of the cooling micro-fluid is related to size and shape of the cross section of the micro-channel 14 in the width W and depth H directions of the micro-channel, as shown in FIG. 4, so the target depth H and the target width W of the open cavity 13 need to be controlled within proper ranges.

Illustratively, the open cavity 13 has a target depth of 30 μm and a target width W of 100 μm. By this arrangement, the strength of the chip 10 is sufficient for stacking operation and breakage is less likely to occur. Furthermore, the chip 10 can achieve face-to-face connection between the active face 12 of one chip with the passive face 11 of an adjacent chip through bonding sites.

It should be noted that FIGS. 3A-4B only schematically illustrate that the cross section of a micro-channel 14 are rectangular but are not meant to limit the chip stack provided by the embodiments of the present disclosure to that particular configuration of the microchannels. In other embodiments, the cross-section of the micro-channel 14 can also be provided in other shapes, such as trapezoidal, semi-circular, etc. without limitation.

In some embodiments, as shown in FIG. 3A, each chip in the chip stack 100 further includes through holes penetrating the chip and conductive posts 20 located in the through holes, wherein the penetrating direction of the through holes is parallel to the stacking direction X of the chips, and the positions of the through holes are located a minimum distance d away from the open cavities 13 (so that no through hole 20 runs through any part of any cavity. In some embodiments, d is equal or greater than a shortest distance between two neighboring conductive posts. The conductor posts 20 in one chip are bonded to the conductor posts 20 in an adjacent chip.

In the stacking direction X of the chips, each chip 10 in the chip stack 100 is provided with through holes (not shown in FIG. 3A) penetrating its thickness; the conductive posts 20 are in the through holes for bonding connection with the conductive posts 20 in adjacent chips, thereby achieving electrical connection between the chips 10. The conductive posts 20 are made of a metal material or a nonmetal material with good electrical conductivity. For example, the metallic material includes at least one of copper, aluminum, silver, gold, and titanium, and the nonmetallic material includes Indium Tin Oxide (ITO).

The positions of the through holes and the positions of the open cavities 13 are away from each other so that the conductive posts 20 in the through holes are completely isolated from the cooling microfluid, avoiding short circuits caused by contact between the cooling microfluid and the conductive posts 20.

In some embodiments, the chips in the chip stack includes at least one of a high bandwidth memory chip and a System-On-Chip.

In this embodiment, each chip 10 may be any semiconductor chip suitable for packaging known to those skilled in the technologies and may be an independent functional chip or an integrated functional chip. For example, the chip stack 100 may include random access memory chips including, but not limited to, dynamic random access memory chips, static random access memory chips, and high bandwidth memory chips, and logic chips including, but not limited to, general purpose processor chips, memory chips, application specific integrated circuit chips (Application Specific Integrated Circuit, ASIC), and field programmable logic array chips (Field Programmable Gate Array, FPGA), system-on-chip chips, and the like.

On the basis of the foregoing embodiments, the embodiments of the present disclosure further provide a method for fabricating a chip stack, where the method is used to prepare any one of the chip stacks provided in the foregoing embodiments, and has corresponding beneficial effects, which are not repeated here to avoid repetition.

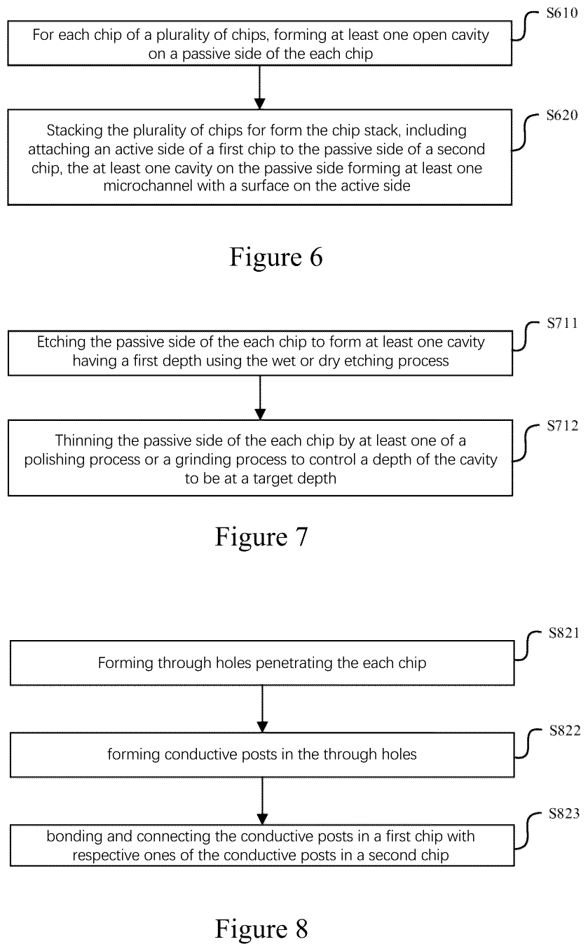

FIG. 6 is a flow chart of a method for manufacturing a chip stack according to an embodiment of the present disclosure. Referring to FIG. 6, the method for fabricating the chip stack includes S610, forming at least one open cavity on the passive surface of each of a plurality of chips. Specifically, to form at least one open cavity on the passive side of a chip, a mask layer with a plurality of gaps is formed first, and the plurality of gaps have preset widths between 30 μm and 200 μm. The gaps, which are not covered by the mask layer, correspond to the open cavities to be formed subsequently. The semiconductor material in each gap is removed chemically or electrochemically to form an open trench, i.e., an open cavity, at the location corresponding to the gap.

In some embodiments, “forming at least one embedded open cavity in the passive surface of the chip” includes forming at least one open cavity in the passive surface of the chip by a photolithographic process followed by wet or dry etching.

In this embodiment, the photolithographic process followed by wet or dry etching may be used to form the open cavity, but other processes known to those skilled in the technologies may used additionally or alternatively.

S620 describes arranging the chips or wafers to form chip stacks, wherein the active surface of one chip of any two adjacent chips is facing the passive surface of the other chip of the two adjacent chips, and the open cavity on the passive surface forms a closed micro-channel with the active surface.

With reference to FIG. 3A, the passive surface 11 of one chip 10 is connected with the active surface 12 of another chip 10 in a face-to-face manner. The open cavity 13 located on the passive surface 11 and the active surface 12 are closely attached together to form a sealed cavity. The sealed cavity forms a micro-channel 14; the surfaces of the open cavity 13 serves as side surfaces and a bottom surface of the micro-channel 14, while the active surface 12 serves as a top surface of the micro-channel 14.

In some embodiments, as shown in FIG. 7, a detailed flowchart of S110 in the method for fabricating the chip stack shown in FIG. 6 is shown. Referring to FIG. 7, “forming at least one embedded open cavity in the passive surface of the chip” further includes S711, forming an open cavity having a first depth on the passive surface of the chip, and S712, thinning the chip polishing or grinding processes the passive surface of the chip and controlling the depth of the open cavity achieve the target depth, wherein the first depth is greater than the target depth and the target depth of the open cavity is 10 μm to 150 μm. Illustratively, the first depth is 50 μm and the target depth is 30 μm.

Specifically, an open cavity with a larger depth is first etched on the passive surface of the chip, and then chemical mechanical polishing (CMP) and/or grinding processes are used to thin the chip by polishing and/or grinding the passive surface. As the thickness of the chip decreases, the depth of the open cavity also gradually decreases, and thinning is stopped when the depth of the open cavity is reduced to the target depth. By the arrangement, the depth of the open cavity is controlled accurately, the passive surface is flatter through the chemical mechanical polishing and grinding process, the performance of the sealed micro-channel is improved, and the cooling micro-fluid is prevented from leaking from the joint of the two chips.

In some embodiments, as shown in FIG. 8, which is a schematic diagram of a detailed process of S120 in the wafer stack fabrication method shown in FIG. 6. Referring to FIG. 8, “arranging the chip stack to form the chip stack” includes S821, for each chip to be used to form the stack of chips, forming through holes penetrating the chip in the thickness direction of the chip, or the stacking direction of the chips.

The through holes are positioned in areas of the chip away from the position of any open cavity so that the conductive posts in the through holes are isolated from the microfluid, and short circuits caused by contact of the microfluid and the conductive posts are avoided.

Specifically, when the through holes are etched in the chip, a photolithographic etching process can be adopted, so that the accuracy of the positions of the through holes is improved; in addition, other semiconductor processing processes may be used, for example, a semiconductor processing process such as wet etching or dry etching may be used, and the present invention is not limited thereto.

S822 forming conductive posts in the through holes. Specifically, conductive posts are formed in each through holes using, for example, an electroplating or electrodeposition process. The conductive posts are used to make electrical connection between adjacent layers of chips. When the conductive posts are formed in the through holes by, for example, deposition or electroplating, the heights of the conductive posts can be greater than of the through holes. Each end of the conductive posts protrudes out of the active surface or the passive surface of the chip, and then the protruding parts are removed using chemical mechanical polishing or grinding and other modes. Thus, the reliability of bonding connection between the conductive posts is ensured.

The material of the conductive posts comprises at least one of copper, aluminum, silver, gold and titanium, and the invention is not limited thereto.

S823, bonding and connecting the conductive posts in each chip with the conductive posts in an adjacent chip.

Referring to FIG. 3A, in the stacking direction X, the passive surface 11 of the chip 10 located at the lower layer faces the active surface 12 of the chip 10 at the upper layer, and the conductive posts 20 of the two chips 10 are aligned and then bonded to each other so that the two chips 10 are connected face to face and the connection pitch is extremely small, thereby not only ensuring the tightness of the micro-channels, but also being beneficial to reducing the overall height of the chip stack.

In some embodiments, “bonding the conductor posts in the chip to the conductor posts in an adjacent chip” includes bonding and connecting the conductive posts in the chip with the conductive posts in the adjacent chips using hybrid bonding technology.

The hybrid bonding can be simultaneously mechanically and electrically connected. The connection reliability is high, and the connection is completely bonded so that the tightness of the micro-channel is ensured and the overall height of the chip stack is reduced.

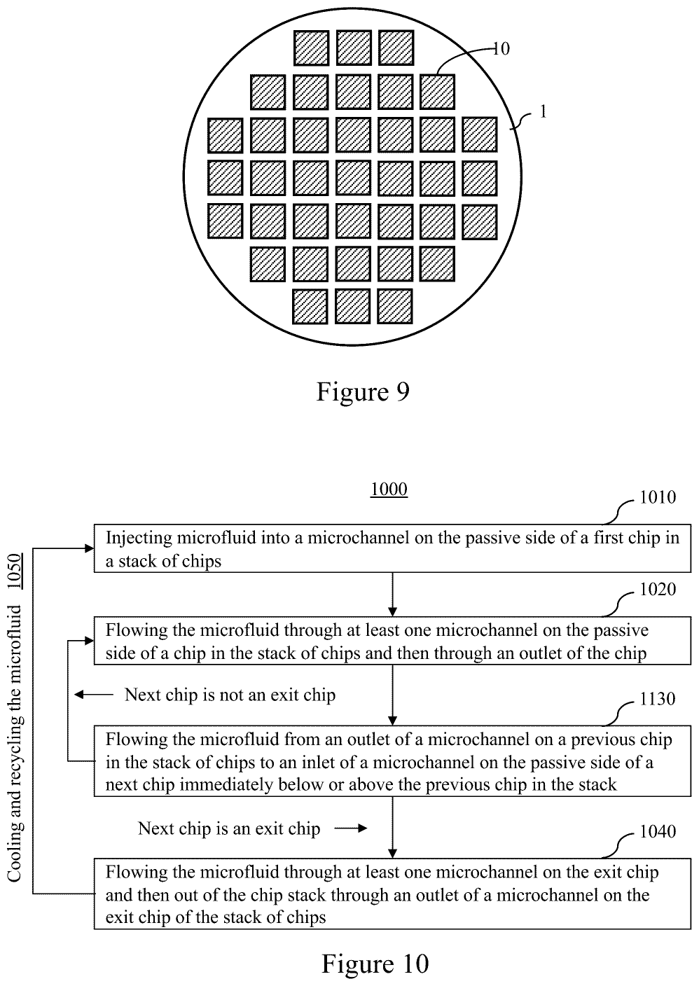

In some embodiments, forming the microchannels, the through vias, and bonding the chips to form chip stacks can be done at wafer level. FIG. 9 shows a wafer 1 including a plurality of chips 10. A method of forming a chip stack comprises forming at least one open cavity 13 on the passive side of each chip 10 by performing an etching process on the back surface (namely the passive surface) of the chip wafer 1 and thinning the wafer 1 from the passive side until the open cavity has a target thickness. Subsequently, the through vias are formed in the thinned wafer, in areas of the chip away from areas occupied by the cavity. The through holes that act as outlets/inlets of the microchannels can be formed by, for example, masking and etching the active side of the wafer, before or after the through vias are formed, or in the same process when the through holes for the through vias are formed, and are masked when the conductive posts in the through vias are formed. This way batch operation of forming the open cavity 13 on the passive surface of the chip is realized and the operation procedure is simplified. The wafers can then be stacked and connected layer by layer using, for example, a hybrid bonding process. The stacked wafers are then diced to form individual chip stacks. Such as the chip stack shown in FIG. 3A. A microchannel is formed by the active surface 12 on one chip and the open cavity 13 on an adjacent chip. Heat generated by the chips can thus be taken away by introducing cooling microfluid so that the heat dissipation of the chips is realized.

FIG. 10 is a flow chart illustrating a method 1000 of operation of the chip stack 100 according to certain embodiments. As shown, the method 1000 includes injecting a microfluid into a microchannel on the passive side of a first chip in a stack of chips (1010), and for each chip from first chip of a stack of chips, the method further comprises flowing the microfluid through at least one microchannel on the passive side of the chip in the stack of chips (1020), and flowing the microfluid from an outlet of a microchannel on the chip in the stack of chips to an inlet of a microchannel on the passive side of another chip immediately below or above the previous chip in the stack of chips (1030). Steps 1020 and 1030 are repeated from one chip to another chip until the microfluid enters and flows through the microchannel of a last or exit chip of the stack of chips, and the method further comprises flowing the microfluid out of the chip stack through an outlet of a microchannel on the last or exit chip of the stack of chips (1040), and cooling the microfluid (1040) (e.g., by running the microfluid through a heat exchanger) before injecting the microfluid into the microchannel on the first chip again.

It should be noted that in this document, relational terms such as “first” and “second” and the like are used solely to distinguish one entity or action from another entity or action without necessarily requiring or implying any actual such relationship or order between such entities or actions. Moreover, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. Without further limitation, an element defined by the phrase “comprising one . . . ” does not exclude the presence of other like elements in a process, method, article, or apparatus that comprises the element.

The foregoing is merely a specific embodiment of the present disclosure to enable one skilled in the technologies to understand or practice the disclosure. Various modifications to these embodiments will be readily apparent to those skilled in the technologies, and the generic principles defined herein may be applied to other embodiments without departing from the spirit or scope of the disclosure. Thus, the present disclosure is not intended to be limited to the embodiments shown and described herein but is to be accorded the widest scope consistent with the principles and novel features disclosed herein.

What is claimed is:

1. A chip stack, comprising: a plurality of stacked chips, each chip in the stacked chips having an active side and a passive side and through vias extending between the active side and the passive side, the passive side having at least one cavity, the plurality of stacked chips including a first chip and an adjacent second chip, the active side of the first chip facing the passive side of the second chip, and the at least one cavity on the passive side of the second chip forming at least one microchannel with a surface on the active side of the first chip.

2. The chip stack of claim 1, wherein the at least one microchannel on the first chip includes first microchannel and the at least one microchannel on the second chip includes a second microchannel that is fluidly coupled to the first microchannel.

3. The chip stack of claim 2, wherein the first microchannel includes a through hole and the first microchannel is fluidly coupled to the second microchannel via the through hole.

4. The chip stack of claim 3, wherein the second microchannel has an outlet at an edge of the second chip.

5. The chip stack of claim 2, further comprising a top chip assembled over the plurality of stacked chips, the top chip including at least one through hole configured to allow injection of a microfluid into the at least one microchannel on a chip of the plurality of stacked chips that is immediately under the top chip.

6. The chip stack of claim 1, wherein the at least one cavity on each chip of the plurality of stacked chips has a depth of 10 μm to 150 μm, and a width of 30 μm to 200 μm.

7. The chip stack of claim 6, wherein a cross section of each cavity has a rectangular shape.

8. The chip stack of claim 1, wherein each through vias includes a conductive post, and conductive posts in the through vias of the first chip are respectively bonded to conductive posts in the through vias of the second chip.

9. The chip stack of claim 1, wherein the plurality of stacked chips includes at least one of a high bandwidth memory chip and a System-On-Chip.

10. A method of fabricating a chip stack, comprising: for each chip of a plurality of chips, forming at least one open cavity on a passive side of the each chip, and forming through vias in the each chip, in areas of the each chip not occupied by the at least one channel on the each chip; stacking the plurality of chips for form the chip stack, including assembling a first chip of the plurality of chips over a second chip of the plurality of chips, the active side of the first chip facing the passive side of the second chip, and the at least one cavity on the passive side of the second chip forming at least one microchannel with a surface on the active side of the first chip.

11. The method of claim 10, wherein forming the at least one open cavity on the passive side of the each chip comprises forming a mask using photolithography on the passive side of the each chip and etching a cavity on the passive side of the each chip using a wet or dry etching process.

12. The method of claim 11, wherein the cavity on the passive side of the each chip is etched to form at least one cavity having a first depth using the wet or dry etching process, and wherein forming the at least one open cavity on the passive side of the each chip further comprises thinning the passive side of the each chip by at least one of a polishing process or a grinding process to thin the each chip and reduce a depth of the cavity to be at a target depth.

13. The method of claim 10, wherein forming through vias in the each chip comprises forming through holes penetrating the each chip, and forming conductive posts in the through holes, and wherein assembling the first chip over the second chip includes bonding and connecting the conductive posts in the first chip with respective ones of the conductive posts in the second chip.

14. The method of claim 9, wherein the conductive posts in the first chip are bonded with respective ones of the conductive posts in the second chip using a hybrid bonding process.

15. The method of claim 10, further comprising forming aat least one through hole to serve as anat least one outlet of athe at least one microchannel on each of at least some of the plurality of chips.

16. A method of temperature control for a chip stack including a plurality of stacked chips, comprising:
injecting a microfluid into a first microchannel on a passive side of a first chip;
from one chip to a next chip in the plurality of stacked chips, successively flowing the microfluid through microchannels on passive sides of the plurality of stacked chips;
collecting the microfluid from an outlet of a microchannel on an exit chip of the plurality of stacked chips; and
cooling the microfluid before injecting the microfluid again into the first microchannel.

17. The method of claim 16, wherein the first chip has an active side facing other chips in the plurality of stacked chips, and the exit chip has an active side facing away from other chips in the plurality of stacked chips.

18. The method of claim 16, wherein the outlet of the microchannel on the exit chip is at an edge of the exit chip.

19. The method of claim 16, wherein the first microchannel has at least one through hole fluidly coupling the first microchannel to a microchannel on a passive side of a chip immediately below the first chip.

20. The method of claim 16, wherein the first chip has an passive side facing other chips in the plurality of stacked chips, and the exit chip has an passive side facing away from other chips in the plurality of stacked chips.
